(19) United States
(12) Patent Application Publication
(10) Pub. No.: US 2006/0017146 A1
(43) Pub. Date: Jan. 26, 2006

(54) IC with stably mounted chip

(76) Inventors: Chung-Hsing Tzu, Zhanghe City (TW); Shih-Yi Chang, Sindian City (TW)

Correspondence Address: DENNISON, SCHULTZ, DOUGHERTY & MACDONALD, 1727 KING STREET, SUITE 105, ALEXANDRIA, VA, 22314, US

(21) Appl. No.: 11/200,054

(22) Filed: Aug. 10, 2005

(30) Foreign Application Priority Data
Jul. 23, 2004 (TW) 093211655

(51) Int. Cl. H01L 23/02; H01L 23/495

(52) U.S. Cl. 257/685; 257/686; 257/676

(57) ABSTRACT

An IC with stably mounted chip includes a chip, a leadframe, a bridge, and an encapsulating compound. The bridge is a flat arch made of a sheet material and includes a horizontal fixing section and a supporting section downward extended from each end of the fixing section. The chip is adhered to a bottom side of the fixing section of the bridge. The leadframe includes a plurality of leads arranged at two opposite sides of the chip. The encapsulating compound is applied to cover the chip, the bridge, and inner portions of the leads to complete a compact IC having a stably mounted chip and a reduced overall thickness. An additional chip may be adhered to a top of the bridge.

### FIELD OF THE INVENTION

The present invention relates to an IC with stably mounted chip, and more particularly to an IC having a stably mounted chip and a reduced overall thickness, and allowing an additional chip to stack on the first chip.

### BACKGROUND OF THE INVENTION

A conventional IC, as shown in FIG. 5, includes a chip 10 and a leadframe 20 located some distance lower than the chip 10. The leadframe 20 includes a plurality of leads 201 made of a sheet material and arranged at two opposite sides of the leadframe 20 for electrically connecting the chip 10 to external elements. The leads 201 are connected to contacts on the chip 10 via a metal wire 30, which may be a golden wire. The chip 10 is usually enclosed by an encapsulating compound 40 to complete the IC. In the above-described IC packaging structure, since the leads 201 are bent in configuration, the completed IC has an increased thickness that does not meet the compactness requirement of the current electronic products.

FIG. 6 is a sectional view showing the packaging structure of another conventional IC. In the second conventional IC, there is a leadframe 20′ having a plurality of leads 201′ in the form of a block each. The leads 201′ are fixedly adhered to a lower surface of a chip 10′ via an adhesive tape 202′ each. After the leads 201′ are connected to contacts on the chip 10′ via a metal wire 30′ each, the chip 10′ is enclosed in an encapsulating compound 40′ to complete the IC. The second conventional IC has a somewhat reduced overall thickness. However, since the chip 10′ is still located above the leads 201′, the thickness of the completed IC is still large. Moreover, since there is only one chip 10′ mounted in the IC in a manner not so stable to ensure a high processing and storing efficiency or to provide multiple functions, the IC does not satisfy the requirement of current electronic products.

### SUMMARY OF THE INVENTION

A primary object of the present invention is to provide an IC having a structure allowing at least one chip to stably mount therein and reduction of an overall thickness of the IC.

Another object of the present invention is to provide an IC having a structure allowing two chips to stably stack therein to enable high processing and storing efficiency and multiple functions.

To achieve the above and other objects, the IC with stably mounted chip according to the present invention includes a chip, a leadframe, a bridge, and an encapsulating compound. The bridge is a flat arch made of a sheet material and includes a horizontal fixing section and a supporting section downward extended from each end of the fixing section. The chip is adhered to a bottom side of the fixing section of the bridge. The leadframe includes a plurality of leads arranged at two opposite sides of the chip. The encapsulating compound is applied to cover the chip, the bridge, and inner portions of the leads to complete a compact IC having a stably mounted chip and a reduced overall thickness. And, an additional chip may be adhered to a top of the bridge, so that two chips are stably stacked in the IC.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a top plan view showing the packaging structure of an IC according to a first embodiment of the present invention;

FIG. 2 is a sectioned front view of the IC of FIG. 1;

FIG. 3 is a sectioned side view of the IC of FIG. 1;

FIG. 4 is a sectioned front view of an IC according to a second embodiment of the present invention;

FIG. 5 is a sectional view showing the packaging structure of a conventional IC; and

FIG. 6 is a sectional view showing the packaging structure of another conventional IC.

### DETAILED DESCRIPTION OF THE PREFERRED EMBODIMENTS

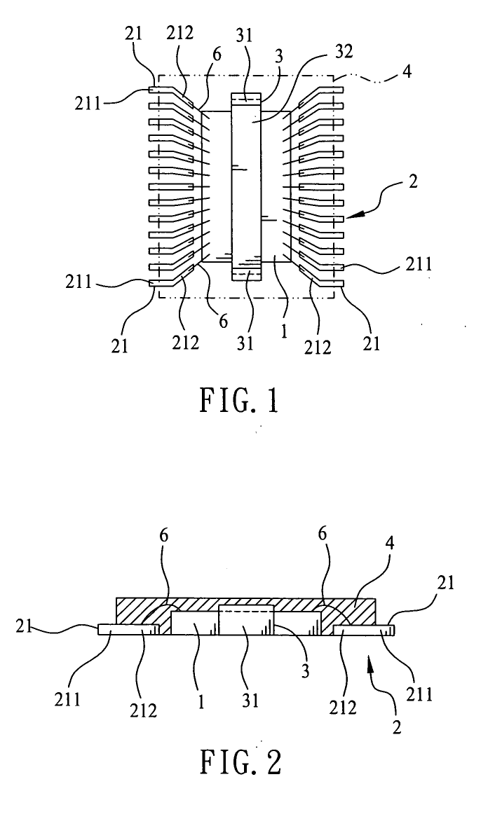

Please refer to FIG. 1 that is a top plan view showing the packaging structure of an IC with stably mounted chip according to a first embodiment of the present invention. As shown, the IC includes a chip 1, a leadframe 2, a bridge 3, and an encapsulating compound 4.

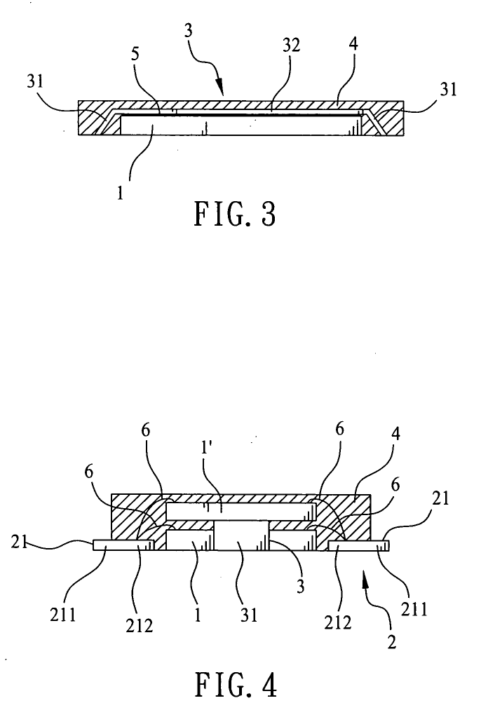

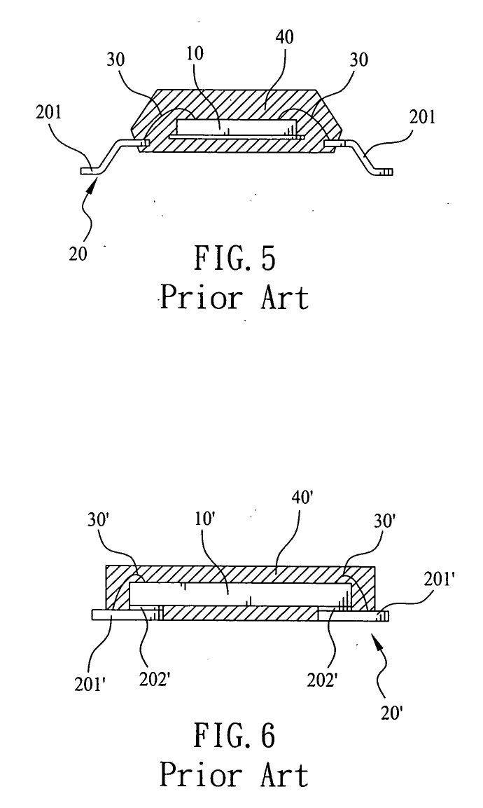

Please refer to FIGS. 1, 2, and 3 at the same time. The chip 1 is a product formed by known techniques and is therefore not described in details herein. The leadframe 2 includes a plurality of leads 21 arranged at two opposite lateral sides or all four sides of the leadframe 2 to electrically connect to external elements. Each of the leads 21 includes an outer and an inner electrical connecting end 211, 212. The encapsulating compound 4 is an insulating material covering the chip 1 and the inner electrical connecting ends 212 of the leadframe 2. The bridge 3 is a flat arch or an inverted U-shaped member made of a sheet material, and includes a supporting section 31 downward extended from each end of a horizontal fixing section 32. The chip 1 is adhered to a bottom side of the fixing section 32 of the bridge 3 via an adhesive layer 5. In the illustrated first embodiment, the leads 21 of the leadframe 2 are arranged at two opposite lateral sides of the chip 1 and electrically connected at the inner electrical connecting ends 212 to the chip 1 via a metal wire 6 each. After the encapsulating compound 4 is applied to enclose the chip 1, the chip 1 is stably mounted in the encapsulating compound 4 to complete the IC of the present invention.

Since the chip 1 is fixedly adhered to the bottom side of the bridge 3 before being packaged with the leadframe 2, the chip 1 is stably positioned and well protected during and after the packaging of the IC. Moreover, since the leads 21 arranged at two or four sides of the leadframe 2 are located at lateral outer sides of the chip 1, allowing the chip 1 to locate at a lower position. In this manner, the completed IC with the chip 1 enclosed in the encapsulating compound 4 has a reduced overall thickness to meet the compactness requirement of current electronic products.

FIG. 4 is a sectioned front view of an IC with stably mounted chip according to a second embodiment of the present invention. The second embodiment is generally structurally similar to the first embodiment, except that an additional chip 1′ is adhered to a top of the fixing section 32 of the bridge 3. Therefore, the IC of the present invention may include two stably stacked chips 1, 1′ to enable high processing and storing efficiency as well as multiple functions thereof.

What is claimed is:

1. An IC with stably mounted chip, comprising a first chip, a leadframe, a bridge, and an encapsulating compound; said bridge being in the form of a flat arch made of a sheet material to include a horizontal fixing section and a supporting section downward extended from each end of said fixing section; the both ends of said bridge are connecting to the said lead frame. Said first chip being adhered to a bottom side of said horizontal fixing section of said bridge via an adhesive layer; said leadframe including a plurality of leads arranged at two opposite lateral sides of said first chip and electrically connected to said first chip via a metal wire each; and said encapsulating compound being applied to cover said chip, said bridge, and an inner portions of said leads.

2. The IC with stably mounted chip as claimed in claim 1, wherein said bridge is an inverted U-shaped member made of a sheet material.

3. The IC with stably mounted chip as claimed in claim 1, further comprising a second chip adhered to a top of said bridge, such that said IC includes two stably stacked chips.
